(19) United States
(12) Patent Application Publication
(10) Pub. No.: US 2004/0180501 A1
(43) Pub. Date: Sep. 16, 2004

(54) Method of forming an embedded ROM

(75) Inventor: Kuang-Wen Liu, Hsinchu (TW)

Correspondence Address: Finnegan, Henderson, Farabow,, Garrett & Dunner, L.L.P., 1300 I Street, N.W., Washington, DC, 20005-3315, US

(73) Assignee: Macronix International Co., Ltd.

(21) Appl. No.: 10/387,488

(22) Filed: Mar. 14, 2003

(51) Int. Cl. H01L 21/8234

(52) U.S. Cl. 438/275

(57) ABSTRACT

A method for manufacturing an embedded device, including providing a substrate including a first region and a second region, forming a gate dielectric layer over the substrate, forming a gate layer over the gate dielectric layer, implanting a first type of impurity ions into the gate layer over the first region and the gate layer over the second region, and forming at least one read-only memory cell with the gate layer implanted with the first type of impurity in the first region and at least one non-memory cell with the gate layer implanted with the first type of impurity in the second region.

### RELATED APPLICATION

This application is related to concurrently-filed U.S. application Ser. No. ______ (Attorney Docket No. 08409.0036-00000), entitled “Method of Method of Modulating Threshold Voltage of a Mask ROM.” This related application is expressly incorporated herein by reference.

### DESCRIPTION OF THE INVENTION

1. Field of the Invention

This invention relates to a method for forming an embedded read-only memory (ROM) and, more particularly, to a method for forming an embedded ROM with narrow line widths.

2. Background of the Invention

A read-only memory (ROM) is a type of non-volatile memory that retains stored data even when no power is provided to the ROM. A mask ROM is also a type of ROM, and its memory cells are programmed by selectively implanting impurity ions into the channel region of a cell transistor during the manufacturing process. The data are loaded into the mask ROM cells. This is known as “programming” or “coding,” and the data are “coded” into the mask that is used to form the ROM. A characteristic of a mask ROM is that after programming, the stored data cannot be altered.

A conventional manufacturing process of a mask ROM first forms the memory cells, e.g., MOS transistors, within each mask ROM product. In general, the source and drain regions, which serve as bit lines, of the cell transistors are formed in the semiconductor substrate. An ion implantation of impurities into the channel regions of the transistors follows using a patterned mask to adjust the threshold voltage of various transistors, thereby “coding” the ROM. This step of the manufacturing process is also known as “code” implantation. Conventional manufacturing process also uses an “in-situ” polysilicon deposition process with impurities already provided during the deposition process.

Selected and ion implanted transistors will have different threshold voltages from the non-selected transistors to differentiate between the logic data of “1” and “0.” Word lines, or gates, connecting the transistors are then formed.

However, the process of manufacturing a mask ROM is generally different from the manufacturing process for a gate logic device, at least because of the different type of impurities provided in the gates of transistors. Specifically, ROM cells generally are doped only with n-type impurities. In contrast, transistors in logic circuits may be doped with both n-type and p-type impurities, depending on the requirements of the product. Consequently, for an embedded product, i.e., a product having both ROM and logic features and functionalities, at least one additional mask is necessary to mask the ROM features while the logic features are being manufactured, or vice versa. This additional manufacturing step increases manufacturing cost and duration, and may attribute to defects in the final product due to the additional manufacturing step of providing the mask layer, patterning the mask layer, and removing the mask layer.

### SUMMARY OF THE INVENTION

In accordance with the present invention, there is provided a method for manufacturing an embedded device that includes providing a substrate including a first region and a second region, forming a gate dielectric layer over the substrate, forming a gate layer over the gate dielectric layer, implanting a first type of impurity ions into the gate layer over the first region and the gate layer over the second region, and forming at least one read-only memory cell with the gate layer implanted with the first type of impurity in the first region and at least one non-memory cell with the gate layer implanted with the first type of impurity in the second region.

Also in accordance with the present invention, there is provided a method for manufacturing an integrated circuit that includes providing a semiconductor substrate, forming a plurality of isolations in the substrate to define at least a memory region for a memory device and a logic region for a logic circuit, wherein the memory region and the logic region are electrically isolated, defining a first region and a second region in the logic region, wherein the first and second regions are electrically isolated, defining a third region and a fourth region in the memory region, forming a gate dielectric layer over the substrate, forming a gate layer over the gate dielectric layer, implanting a first type of impurity ions into the gate layer over the first and third regions, and implanting a second type of impurity ions into the gate layer over the second and fourth regions.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the objects, advantages, and principles of the invention.

In the drawings,

FIG. 1 illustrates the layout a memory device consistent with one embodiment of the present invention; and

FIGS. 2-9 are cross-sectional views of the manufacturing steps of a semiconductor device with embedded read-only memory consistent with one embodiment of the present invention.

### DESCRIPTION OF THE EMBODIMENTS

Reference will now be made in detail to the preferred embodiments of the invention, examples of which are illustrated in the accompanying drawings. Wherever possible, the same reference numbers will be used throughout the drawings to refer to the same or like parts.

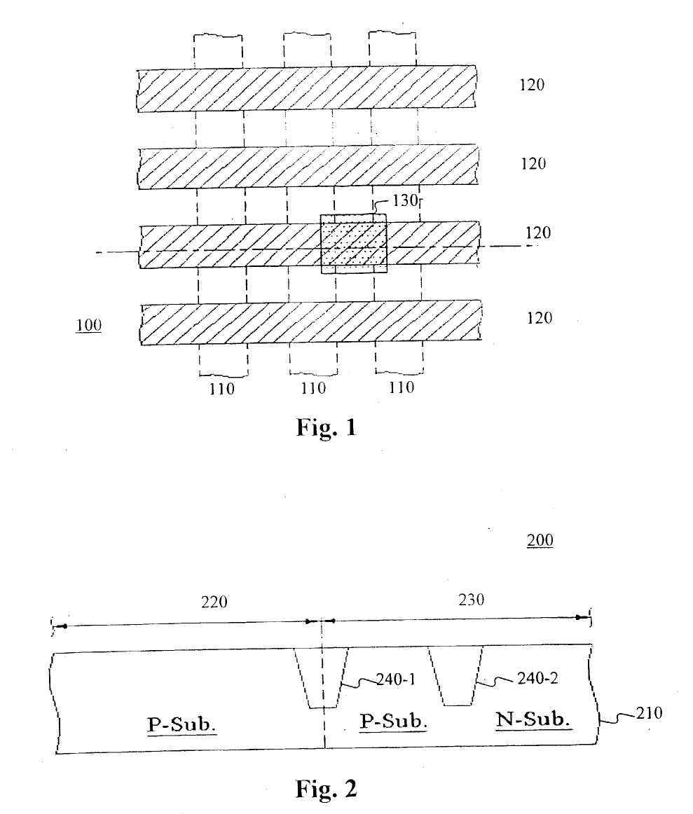

FIG. 1 illustrates the layout of a memory device 100 consistent with one embodiment of the present invention. Referring to FIG. 1, ROM 100 includes a plurality of memory cells (not numbered) defined by a plurality of bit lines 110 and a plurality of word lines 120, each memory cell corresponding to one of bit lines 110 and one of word lines 120. One memory cell is proximately represented as a dotted region 130, referred to as “selected memory cell” hereinafter. Selected memory cell 130 has a different logic state from a memory cell in other regions, or a non-selected memory cell. For example, the selected memory cells may be at a logic “1” state and the non-selected memory cells are at a logic “0” state. The doping and the concentration thereof of the gate, or one of word lines 120 corresponding to a memory cell, is the primary factor in determining the characteristics, e.g., logic state, of a memory cell.

Consistent with the present invention, there is provided a method for fabricating a ROM cell array embedded in a logic product that includes a logic MOS circuit. FIGS. 2-9 show cross-sectional views of an embedded semiconductor device 200 consistent with one embodiment of the present invention.

Referring to FIG. 2, there is provided a semiconductor substrate 210 including at least two regions, a memory region 220 for the ROM cell array and a logic region 230 for a logic circuit. A plurality of isolations 240, such as shallow trench isolations (“STIs”) or field oxides, are formed in substrate 210. As shown in FIG. 2, a first isolation 240-1 electrically isolates memory region 220 and logic region 230, and a second isolation 240-2 is formed in logic region 230 for electrically isolating two transistors to be formed later.

For purposes of illustration, only one NMOS transistor and one PMOS transistor are formed in logic region 230. Substrate 210 in memory region 220 is doped with a p-type impurity, in logic region 230 where the NMOS transistor is to be formed is doped with a p-type impurity, and in logic region 230 where the PMOS transistor is to be formed is doped with an n-type impurity. In other words, memory region 220 and the NMOS transistor are formed in p-wells, and the PMOS transistor is formed in an n-well. However, it is to be understood that the dopant type of these parts of substrate 210 is not critical to purposes of this invention, and logic region 230 may include more transistors.

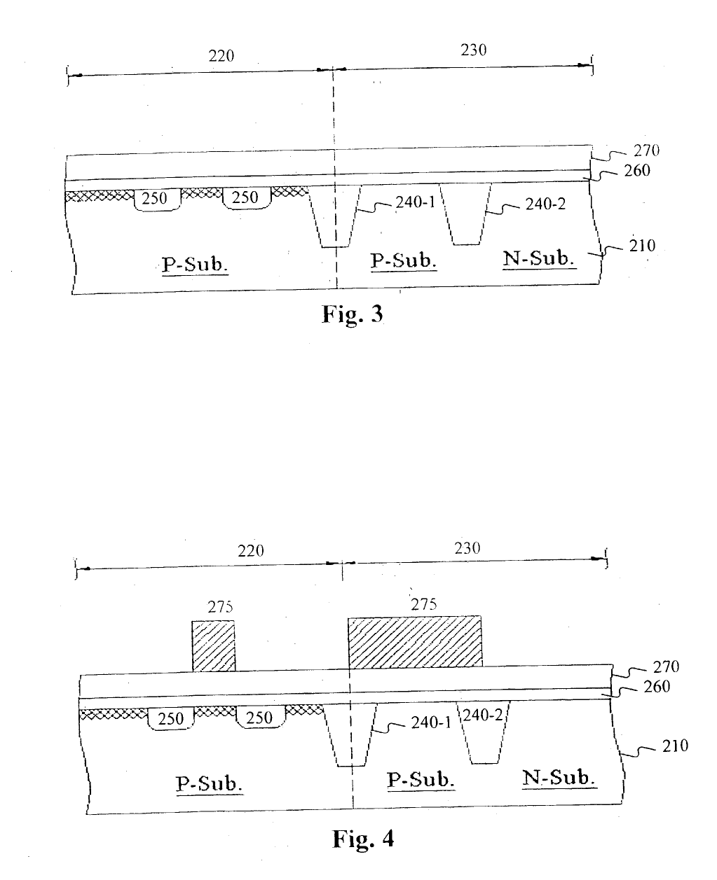

Referring to FIG. 3, a plurality of bit lines 250 are formed by doping corresponding parts of memory region 220. Bit lines 250 also correspond to the source and drain regions of a memory cell. In one aspect, bit lines 250 are formed through ion implantation of a first type of impurity ions. In another aspect, a part of substrate 210 under word lines (not shown) is also simultaneously doped at the same time as bit lines 250, i.e., the channel region between bit lines 250. The channel region is rendered conductive.

After bit lines 250 and channels (not numbered) therebetween are formed, a layer of gate dielectric 260 is provided over substrate 210, including STIs 240 and bit lines 250. In one aspect, gate dielectric 260 comprises silicon dioxide. Gate dielectric layer 260 may be grown or deposited using any conventional method, such as thermal oxidation or chemical vapor deposition (CVD). Gate dielectric layer 260 can also be deposited in two steps such that the thickness thereof over memory region 220 is different from that over logic region 230, as some product specification may require.

Following the formation of gate dielectric 260, a gate layer 270, or word line, is formed over gate dielectric layer 260. In one aspect, gate layer 270 comprises polysilicon. In another aspect, gate layer 270 is provided through CVD.

Referring to FIGS. 4 and 5, a first mask 275, e.g., photoresist, is provided prior to implanting a second type of impurity ions into gate layer 270. First mask 275 is patterned to cover selected memory cells and the part of logic region 230 where a first type transistor is to be formed. The second type of ions are then implanted into gate layer 270. In one aspect, the second type of ions are p-type ions, and the first type transistor is NMOS transistor. Referring to FIG. 5, first parts 280 of gate layer 270 are implanted with the second type of ions. First mask 275 is removed after the implantation of the second type of ions.

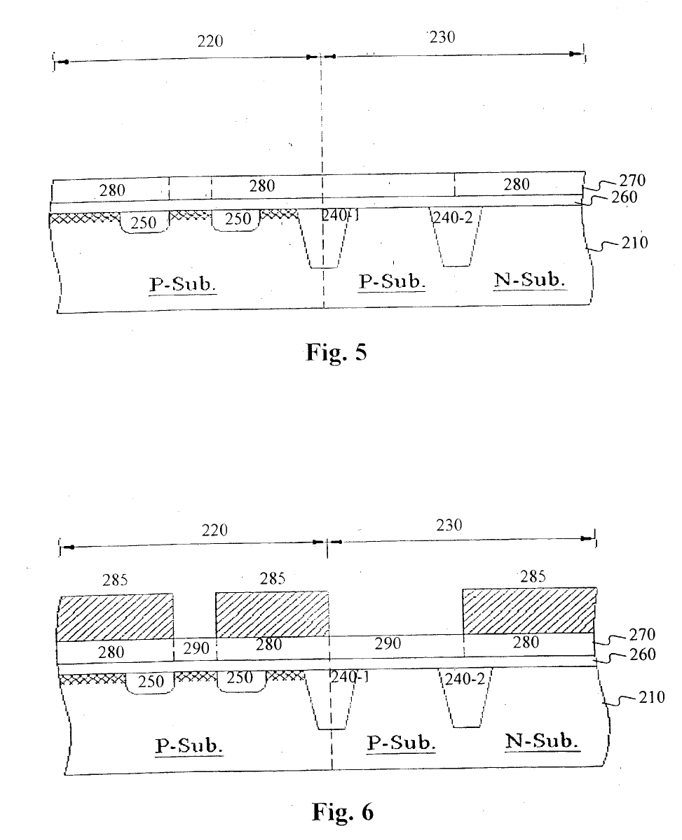

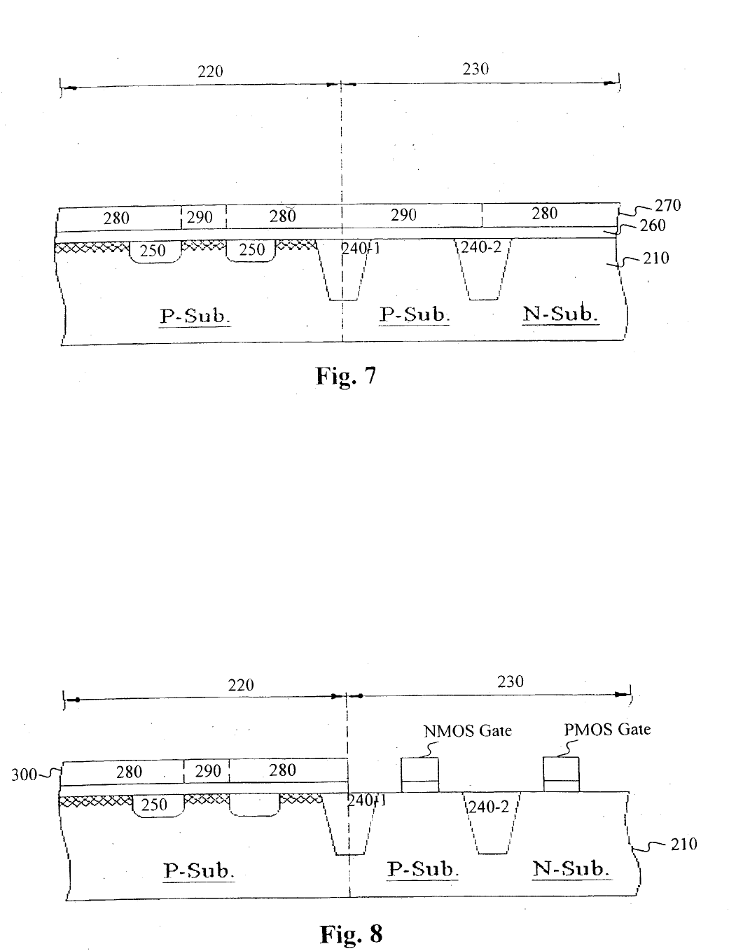

Referring to FIGS. 6 and 7, a second mask 285, e.g., photoresist, is provided prior to implanting a third type of impurity ions into gate layer 270. Second mask 285 is patterned to cover at least first parts 280 of gate layer 270. The third type of ions are implanted into second parts 290 of gate layer 270. The third type of ions may be n-type or p-type. Gate layer 270 has a thickness, and doped second part 290 in memory region 220 has a depth. In one embodiment, gate layer 270 thickness is greater than the depth of doped second part 290 in memory region 220. In another aspect, second part 290 of gate layer 270 in logic region 230 corresponds to the gate of a second type transistor, e.g., a PMOS transistor. Second mask 285 is then removed.

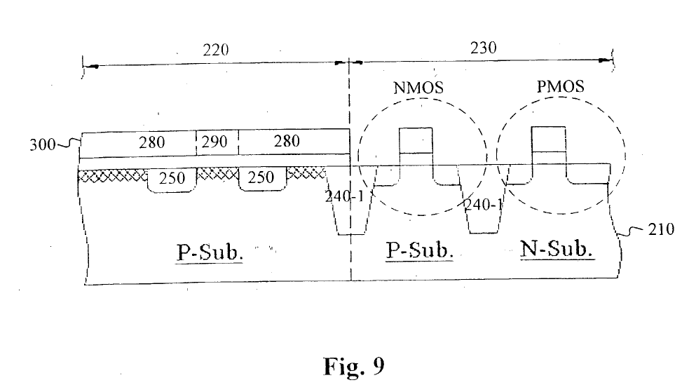

Referring to FIG. 8, the gate layer, including first parts 280 and second parts 290, and gate dielectric layer 260 are patterned and etched to form word lines 300 in memory region 220 and the gates (not numbered) of the NMOS transistor and the PMOS transistor.

Referring to FIG. 9, a conventional MOS process is performed to complete formation of the NMOS transistor and the PMOS transistor in logic region 230, and the ROM cell in memory region 220. This manufacturing process is well-known to one skilled in the art and is therefore not described in detail.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for manufacturing an embedded device, comprising:
providing a substrate including a first region and a second region;
forming a gate dielectric layer over the substrate;
forming a gate layer over the gate dielectric layer;
implanting a first type of impurity ions into the gate layer over the first region and the gate layer over the second region; and
forming at least one read-only memory cell with the gate layer implanted with the first type of impurity in the first region and at least one non-memory cell with the gate layer implanted with the first type of impurity in the second region.

2. The method of claim 1, further comprising forming at least one isolation to electrically isolate the first and second regions.

3. The method of claim 1, wherein the gate dielectric comprises silicon dioxide.

4. The method of claim 1, wherein the gate layer comprises polysilicon.

5. The method of claim 1, wherein the first type of impurity is an n-type impurity.

6. The method of claim 1, wherein the first type of impurity is a p-type impurity.

7. The method of claim 1, further comprising forming one or more bit lines in the substrate by implanting a second type of impurity ions into the substrate.

8. The method of claim 7, wherein the second type of impurity is a p-type impurity.

9. The method of claim 7, wherein the second type of impurity is an n-type impurity.

10. The method of claim 7, further comprising implanting the second type of impurity into a region in the substrate between two of the bit lines.

11. The method of claim 1, further comprising forming a well region of a first type in the first region, and a well region of a second type in the second region, wherein the first type is different from the second type.

12. A method for manufacturing an integrated circuit, comprising:
providing a semiconductor substrate;
forming a plurality of isolations in the substrate to define at least a memory region for a memory device and a logic region for a logic circuit, wherein the memory region and the logic region are electrically isolated;
defining a first region and a second region in the logic region, wherein the first and second regions are electrically isolated;
defining a third region and a fourth region in the memory region;
forming a gate dielectric layer over the substrate;
forming a gate layer over the gate dielectric layer;
implanting a first type of impurity ions into the gate layer over the first and third regions; and
implanting a second type of impurity ions into the gate layer over the second and fourth regions.

13. The method of claim 12, wherein the plurality of isolations comprise shallow trench isolations.

14. The method of claim 12, further comprising forming one or more bit lines in the memory region of the substrate by implanting a third type of impurity ions.

15. The method of claim 12, wherein forming a gate dielectric layer over the substrate comprises depositing a layer of the gate dielectric of a first thickness over the memory region, and depositing a layer of the gate dielectric of a second thickness over the logic region, wherein the first thickness is different from the second thickness.

16. The method of claim 12, further comprising patterning the layer of polysilicon and the gate dielectric layer to form one or more word lines over the memory region, one or more first gate structures over the first region, and one or more second gate structures over the second region.

17. The method of claim 12, wherein implanting a first type of impurity ions into the gate layer over the first and third regions comprises masking the second and fourth regions prior to implanting the first type of impurity ions.

18. The method of claim 12, wherein implanting a second type of impurity ions into the gate layer over the second and fourth regions comprises masking the first and third regions prior to implanting the second type of impurity ions.
